(19) United States
(12) Patent Application Publication
(10) Pub. No.: US 2006/0255293 A1
(43) Pub. Date: Nov. 16, 2006

(54) Method for decreasing chemical diffusion in parylene and trapping at parylene-to-parylene interfaces

(75) Inventors: Yu-Chong Tai, Pasadena, CA (US); Damien C. Rodger, Los Angeles, CA (US); Wen Li, Pasadena, CA (US); Angela Tooker, Alhambra, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: California Institute of Technology, Pasadena, CA (US)

(21) Appl. No.: 11/408,809

(22) Filed: Apr. 21, 2006

Related U.S. Application Data
(60) Provisional application No. 60/673,488, filed on Apr. 21, 2005.

(51) Int. Cl. G21G 5/00; C23C 16/00

(52) U.S. Cl. 250/492.1; 118/725

(57) ABSTRACT

Systems and methods for improving the adherence of poorly-adherent parylene-to-parylene films or layers and/or altering the water and chemical permeability of the parylene layers. A device having two or more parylene layers is heated in a reduced pressure treatment chamber at a temperature above the deposition temperature of the parylene (e.g., from about room temperature to several hundreds of degrees Celsius) for an extended period of time (e.g., a few hours up to several days). The methods of the present invention have been shown to convert poorly-adherent and/or water-permeable films to optimally-adherent and/or relatively water-impermeable films.

### CROSS-REFERENCES TO RELATED APPLICATIONS

The present application claims priority to U.S. Provisional Patent Application No. 60/673,488, filed Apr. 21, 2005, which is hereby incorporated herein by reference for all purposes.

### STATEMENT AS TO RIGHTS TO INVENTIONS MADE UNDER FEDERALLY SPONSORED RESEARCH AND DEVELOPMENT

This invention was made with Government Support under Grant No. EEC0310723 awarded by the National Science Foundation. The Government may have certain rights in the invention.

### BACKGROUND OF THE INVENTION

The present invention relates generally to parylene-based devices and fabrication processes, and more particularly to systems and methods for decreasing chemical diffusion in parylene-based devices and fabrication processes, and for increasing adhesion of parylene-parylene layers in such devices and processes.

Parylene, and especially parylene C, is used in many applications in mechanical engineering, electrical engineering, and biomedical engineering. Its use as a substrate and as a coating for biomedical devices is especially prevalent due to its demonstrated USP Class VI biocompatibility. As a material for ocular devices, for example, the use parylene is being widely explored due to its flexibility and mechanical strength as well as its demonstrated intraocular biocompatibility.

One drawback to the use of parylene as a flexible, biocompatible, near-hermetic base material or coating in the fabrication and microfabrication of devices for biomedical as well as non-biomedical use is the problem of water/chemical permeability of the parylene. If water permeates the parylene, electronics underlying the parylene may fail.

Another drawback of using parylene is delamination of parylene from separately deposited layers when used in multi-step processes. If delamination of one parylene layer from another occurs, device failure will almost inevitably result.

These problems stem from several possible chemical and mechanical mechanisms. Of these, perhaps the most likely are the lack of cross-weaving at the interface of two independently deposited parylene layers and low density of the parylene when deposited (as is normal) in a chamber at room-temperature.

Therefore, it is desirable to provide systems and methods that overcome the above and other problems.

### BRIEF SUMMARY OF THE INVENTION

The present invention provides systems and methods for improving adhesion of adjacent parylene layers in a device and for reducing or eliminating permeability of paryelene.

According to the invention, a device having two or more parylene layers is heated at a temperature above the deposition temperature of the parylene (e.g., from about room temperature to several hundreds of degrees Celsius) for an extended period of time (e.g., a few hours up to several days) in a reduced pressure environment. In one aspect, an inert gas such as nitrogen is used as a backfill during the heat treatment process.

According to one aspect, a method is provided for improving the adherence of poorly-adherent parylene-to-parylene films or layers and/or altering the water and chemical permeability of the parylene layers. The methods of the present invention have been shown to convert poorly-adherent and/or water-permeable films to optimally-adherent and/or relatively water-impermeable films.

According to one aspect, a treatment chamber is provided that includes a platform for holding one or more parylene-based devices. The treatment chamber includes or is coupled with a vacuum pump or other pressure reducing mechanism for controlling the pressure of the enclosed chamber, and one or more heat radiating elements for controlling the ambient temperature of the chamber.

According to one aspect of the present invention, a method is provided for improving parylene-to-parylene adhesion in a device having multiple parylene layers. The method typically includes providing a device having multiple parylene layers in a vacuum chamber, and heating at least two adjacent parylene layers of the device at or to a temperature that is greater than a deposition temperature at which the parylene layers were formed for at least an amount of time sufficient to enhance adhesion of the at least two parylene layers. In certain aspects, each parylene layer includes one of parylene C, parylene F, parylene A, parylene AM, parylene N, parylene D or parylene HT.

According to another aspect of the present invention, a method is provided for improving parylene-to-parylene adhesion in a device having multiple parylene layers. The method typically includes providing a device having multiple parylene layers in a treatment chamber, and heating the treatment chamber to a temperature that is greater than a deposition temperature at which the parylene layers were formed for at least an amount of time such that adhesion of the at least two parylene layers is improved.

According to yet another aspect of the present invention, a treatment chamber is provided that typically includes an enclosed housing structure defining a chamber, the structure having a first port coupled with a pressure reducing mechanism and a second port coupled with a backfill source. The treatment chamber also typically includes' a platform within the chamber that is configured to hold one or more parylene based devices, and one or more heating elements for controlling the ambient temperature of the treatment chamber. In operation, the heating elements hold the ambient temperature of the chamber at or above a deposition temperature of parylene, and when a device having multiple parylene layers is held by said platform at or above that temperature for a period of time between about two hours and several days, the adhesion between adjacent parylene layers of the device is improved.

According to yet a further aspect of the present invention, a method is provided for improving parylene adhesion in a device having one or multiple parylene layers. The method typically includes providing a device having a parylene layer on a substrate in a vacuum chamber, and heating the device at or to a temperature that is greater than a deposition temperature at which the parylene layer was formed for at least an amount of time sufficient to enhance adhesion of the parylene layer to the substrate. In certain aspects, the substrate includes a material selected from the group consisting of silicon, silicon dioxide, glass, a polymer, a ceramic, and a metal.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates an example of a fabrication process involving multiple parylene layer depositions, as well as a multiple parylene layer device.

FIG. 2 illustrates the chemical structures of the three most common parylenes.

FIG. 3 illustrates a system for processing fabricated multiple parylene layer devices according to one embodiment.

FIG. 4 illustrates a parylene-based device undergoing heat treatment in the system of FIG. 3.

FIG. 5 illustrates another view of a parylene-based device undergoing heat treatment in the system of FIG. 3.

### DETAILED DESCRIPTION OF THE INVENTION

The present invention provides systems and methods for improving adherence of multiple parylene layers and for decreasing the permeability of water and chemicals in parylene layers.

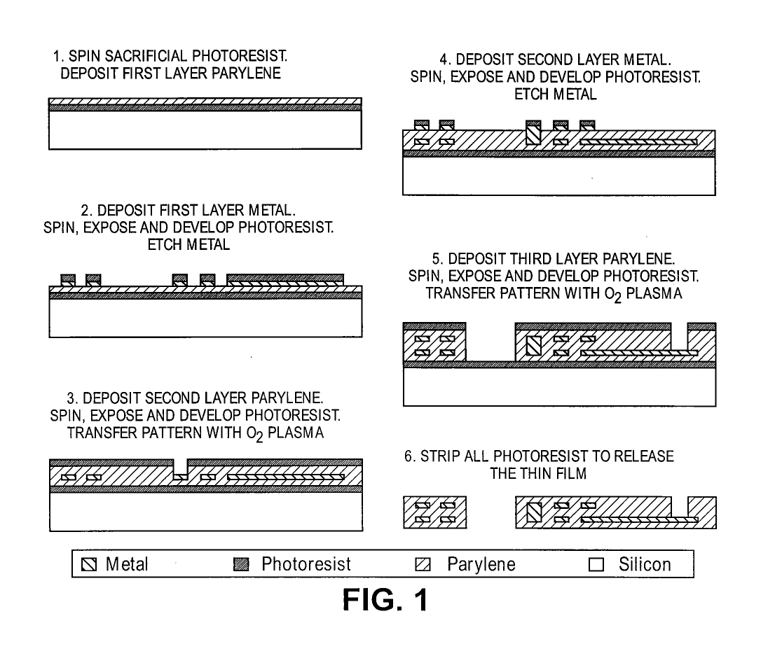

Most parylene-based device fabrication processes use a multi-layer microfabrication paradigm. These processes usually include a parylene deposition step followed by some type of intervening processing step or steps and then a second parylene deposition step. Parylene deposition can occur at room temperature, e.g., in a conformal vapor deposition process, or at higher temperatures. The nature of this second parylene deposition step and the intervening process steps typically produce a non-seamless interface between the two layers of parylene. One example of such a multi-layer fabrication process is shown in FIG. 1. FIG. 1 also shows an example of a multiple-parylene layer device. U.S. patent application Ser. No. 11/130,814, titled “PARYLENE-BASED FLEXIBLE MULTI-ELECTRODE ARRAYS FOR NEURONAL STIMULATION AND RECORDING AND METHODS FOR MANUFACTURING THE SAME,” filed May 16, 2005, and which is hereby incorporated by reference in its entirety, discloses examples of devices including multiple parylene layers and methods for fabricating such devices. Upon immersion of an actual multiple-parylene layer device in water or other substances, it can be seen that such substances can penetrate the parylene layers and may indeed become retained at the interface (as can typically be noticed under simple optical observation).

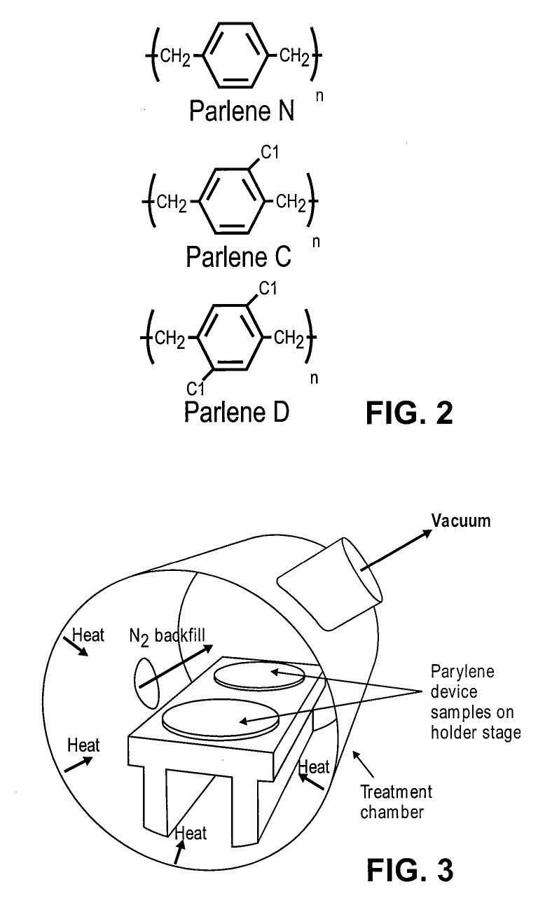

Parylene is a USP Class VI biocompatible polymer that can be deposited through a highly-conformal vapor deposition process. Types of parylene include parylene C, F, A, AM, N, D and HT. Of the three most common types of parylene, shown in FIG. 2, parylene C is perhaps the most widely used in industry. The advantages of the use of parylene include its proven biocompatibility, its strength and flexibility (e.g., Young's modulus≈4 GPa), its conformal pinhole-free room-temperature deposition, its low dielectric constant (≈3) and high volume resistivity (>10¹⁶ Ω-cm), its transparency, and its ease of manipulation using standard microfabrication techniques such as reactive ion etching (RIE). Several research groups have used parylene C deposition as a method of creating a biocompatible, water-blocking seal around electrode arrays typically fabricated using a polyimide substrate. This is necessary because most polyimides have a moisture absorption that is more than an order of magnitude higher than that of parylene C. Some specialized polyimide films have lower moisture absorption, but they require high-temperature curing steps that are generally not post-IC compatible, and their use in permanent medical implants is not permitted.

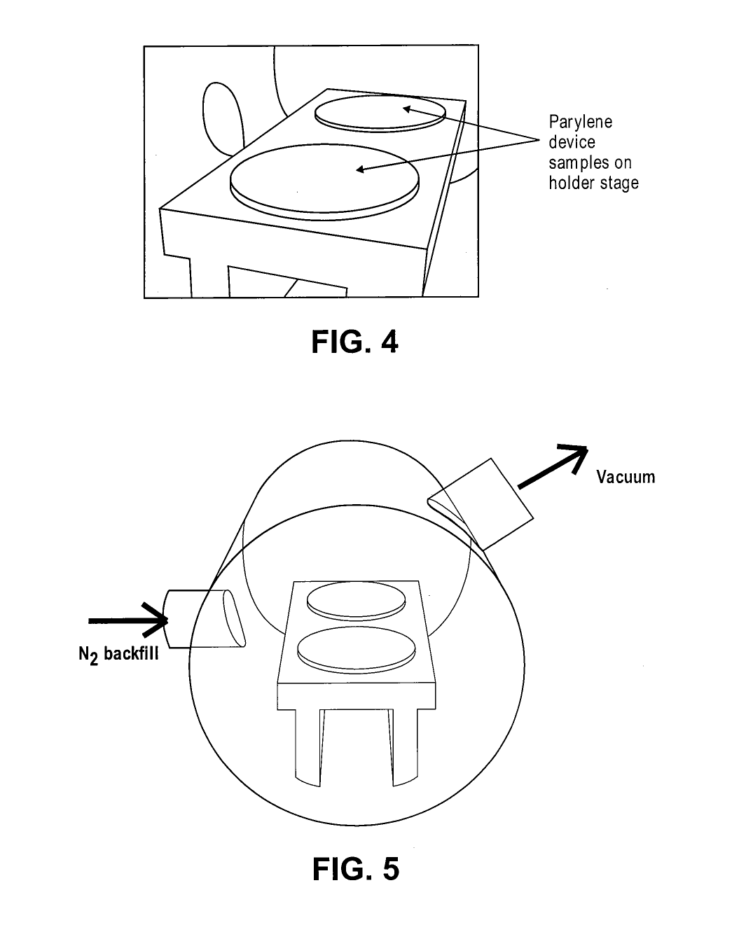

According to one embodiment, the adhesion and water penetration issues associated with multiple-parylene layer devices and fabrication methods are averted or substantially reduced by heating a fabricated multi-parylene layer device to a temperature generally greater than the parylene deposition temperature for an extended period of time. This treatment optimally is carried out in a vacuum oven environment with nitrogen, or other insert gas backfill. An example of a treatment setup according to one embodiment is shown in FIGS. 3-5. As shown, the setup includes a treatment chamber and a holding platform for holding one or more fabricated devices. The treatment chamber includes one or more heating elements and heat reflection elements (not shown) for controlling the ambient temperature of the chamber and/or concentrating the temperature at certain points in the chamber (e.g., reducing or creating heat gradients within the chamber). A vacuum port in the housing of the treatment chamber provides fluid communication to a vacuum pump or other pressure reducing or evacuation device for controlling the pressure of the chamber. In certain aspects, the chamber is held at a pressure of about 0.1 atm. or less. A backfill port in the housing provides fluid communication with a backfill source, such as a canister or reservoir of nitrogen gas or other inert gas. It should be understood that the treatment chamber may include additional processing equipment and inlet/outlet ports. For example, the treatment chamber may contain all or a portion of the equipment needed to fabricate a multiple parylene layer device. In certain aspects, the treatment chamber may be part of a fabrication line, for example, coupled with upstream and/or downstream processing stations by way of a conveyor system that automatically moves fabricated and partially fabricated devices from one station to the next.

In one aspect, the temperature of the chamber is heated to greater than about 80° C. In certain aspects, the temperature of the chamber is held at a temperature that is greater than about 100° C. for a period of time. For example, a simple treatment at 180° C. or 200° C. for about 3 days or less has been shown to convert a poorly-adherent and water-permeable device to a device that does not suffer from these problems. These are only examples, as a wide range of ambient temperatures, e.g., from about a little above room temperature (e.g., about 30° C.) to several hundred ° C. could work. The period of time required may vary with the ambient temperature of the chamber. The higher the ambient temperature of the chamber, the quicker the device (and the parylene layers) comes to an equilibrium temperature. It is desirable that a multiple parylene layered device, or at least the parylene layers, be held at or above a specific equilibrium temperature (which is at or above the deposition temperature of parylene) for an extended period of time to ensure that the adhesion reaction occurs such that the parylene layers sufficiently adhere to one another and the desired device properties are achieved.

Without being held to any particular theory, the adhesion reaction that improves the parylene-to-parylene adherence and the impermeability of parylene works most likely by causing migration of the material at the parylene-to-parylene junction (as if by annealing or re-flowing), increasing the density of the parylene due to an increase in temperature, removing contaminants (such as residual dimers) from the parylene or by way of other as yet not understood mechanisms.

In one aspect, additional physical and/or chemical treatments can be used to clean the devices and to facilitate the adhesion reaction. For example, an oxygen plasma can be applied to a layer of parylene to remove contaminants prior to deposition of a second parylene layer. Similarly, contaminants can be removed by applying acetone or HF or by removing or stripping resist that may have been used.

In one aspect, the processes of the present invention also improve adhesion between one or more layers of parylene and other materials that may be used in the fabrication of a device. For example, the adhesion between parylene and silicon, silicon dioxide, glass, polymers, ceramics, metals and other materials is improved.

While the invention has been described by way of example and in terms of the specific embodiments, it is to be understood that the invention is not limited to the disclosed embodiments. To the contrary, it is intended to cover various modifications and similar arrangements as would be apparent to those skilled in the art. For example, a “device” or “fabricated device” can include any device having two or more parylene layers at any point during a device fabrication process, e.g., on a wafer or substrate, after removal from a substrate, etc. A device need not be a final device configuration; additional processing steps and/or parylene deposition steps may occur after treatment in a heat treatment chamber. Therefore, the scope of the appended claims should be accorded the broadest interpretation so as to encompass all such modifications and similar arrangements.

What is claimed is:

1. A method of improving parylene-to-parylene adhesion in a device having multiple parylene layers, comprising:
providing a device having multiple parylene layers in a vacuum chamber;
heating at least two adjacent parylene layers of the device to a temperature that is greater than a deposition temperature at which the parylene layers were formed for at least an amount of time sufficient to enhance adhesion of the at least two parylene layers.

2. The method of claim 1, wherein the vacuum chamber is at a pressure of about 0.1 atm or lower.

3. The method of claim 1, further comprising introducing a nitrogen backfill into the vacuum chamber.

4. The method of claim 1, further comprising introducing a backfill including an inert gas into the vacuum chamber.

5. The method of claim 1, wherein the temperature is at least 80° C.

6. A method of improving parylene-to-parylene adhesion in a device having multiple parylene layers, comprising:
providing a device having multiple parylene layers in a treatment chamber;
heating the treatment chamber to a temperature that is greater than a deposition temperature at which the parylene layers were formed for at least an amount of time such that adhesion of the at least two parylene layers is improved.

7. The method of claim 6, wherein at least two adjacent parylene layers of the device are held at an equilibrium temperature that is greater than the deposition temperature at which those parylene layers were formed.

8. The method of claim 6, wherein the amount of time is at least two hours.

9. The method of claim 6, wherein the amount of time is at least two days.

10. The method of claim 6, wherein the temperature is greater than about 80° C.

11. The method of claim 6, wherein the temperature is between about 100° C. and about 200° C.

12. The method of claim 6, wherein the temperature is greater than about 200° C.

13. The method of claim 6, further comprising introducing a backfill including an inert gas into the treatment chamber.

14. The method of claim 6, wherein water permeability of the at least two parylene layers is reduced.

15. A treatment chamber, comprising:
an enclosed housing structure defining a chamber, the structure having a first port coupled with a pressure reducing mechanism and a second port coupled with a backfill source;
a platform within said chamber that is configured to hold one or more parylene based devices;
one or more heating elements for controlling the ambient temperature of the treatment chamber, wherein the heating elements hold the ambient temperature of the chamber at or above a deposition temperature of parylene,
wherein when a device having multiple parylene layers is held by said platform for a period of time between about two hours and several days, the adhesion between adjacent parylene layers of the device is improved.

16. The chamber of claim 15, wherein the backfill source includes an inert gas.

17. The chamber of claim 15, wherein the pressure reducing mechanism includes a vacuum pump.

18. The method of claim 15, wherein the ambient temperature is greater than about 80° C.

19. The method of claim 15, wherein the ambient temperature is between about 100° C. and about 200° C.

20. The method of claim 15, wherein the ambient temperature is greater than about 200° C.

21. The method of claim 1, wherein each parylene layer comprises one of parylene C, parylene F, parylene A, parylene AM, parylene N, parylene D or parylene HT.

22. A method of improving parylene adhesion in a device having one or multiple parylene layers, comprising:
providing a device having a parylene layer on a substrate in a vacuum chamber;
heating the device at a temperature that is greater than a deposition temperature at which the parylene layer was formed for at least an amount of time sufficient to enhance adhesion of the parylene layer to the substrate.

23. The method of claim 22, wherein the substrate comprises a material selected from the group consisting of silicon, silicon dioxide, glass, a polymer, a ceramic, and a metal.
